(19) United States
(12) Patent Application Publication
(10) Pub. No.: US 2009/0195272 A1
(43) Pub. Date: Aug. 6, 2009

(54) Data transmission system for exchanging multi-channel signals

(75) Inventor: Noboru Okuzono, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/320,644

(22) Filed: Jan. 30, 2009

(30) Foreign Application Priority Data
Feb. 4, 2008 (JP) 2008-023622

(51) Int. Cl. H03L 7/00

(52) U.S. Cl. 327/141

(57) ABSTRACT

A receiver circuit is provided with: a plurality of input terminals; a plurality of hold circuits holding reception signals received by the plurality of input terminals; a detector circuit detecting clock bits from selected one of the reception signals to recover a clock signal in response to the detected clock bits; and a clock circuit connected to the detector circuit and generating one or more internal clock signals from the clock signal. The hold circuits commonly receive the internal clock signal(s) and perform sampling of the reception signals commonly in synchronization with the internal clock signal(s).

### INCORPORATION BY REFERENCE

This application claims the benefit of priority based on Japanese Patent Application No. 2008-023622, filed on Feb. 4, 2008, the disclosure of which is incorporated herein by reference.

### BACKGROUND OF THE INVENTION

1. Field of the Invention

The present invention relates to a data transmission system, in particular, to a data transmission system which transmits data by using multi-channel signals.

2. Description of the Related Art

As known in the art, data transmission systems often use multi-channel signals for transmitting data. Japanese Open Laid Patent Application No. P2006-339858 discloses conventional transmitter/receiver circuits for exchanging signals over a plurality of channels. FIG. 13 is a schematic view illustrating the configuration of the disclosed transmitter/receiver circuits. Transmitting-side and receiving-side chips 206 each incorporate a plurality of input circuits 202 and a plurality of output circuits 207 which are associated with transmitting channels, respectively. The input circuits 202 each include a CDR (clock data recovery) circuit 201, a receiver 203, and a serial-parallel converter 204. In each chip 206, the respective input circuits 202 and output circuits 207 receive multi-phase clock signals from a common PLL circuit 205. The output circuits 207 are each configured to generate a clock-embedded signal by superposing a clock signal on desired data, and to send the generated clock-embedded signal over the corresponding transmission channel. In the receiving-side chip 206, the receiver circuits 202 each receive the transmitted signal incorporating the embedded clock from the corresponding transmitter circuit, and detect the phase of the embedded clock by a phase detector. The receiver circuits 202 are each designed to generate a clock signal with a desired phase through mixing four-phased clock signals received from the PLL circuit 5. The receiver circuits 202 thus constructed each generate an internal clock with a desired phase through adjusting the phase thereof in response to the output of the phase detector, and perform sampling of the received signal in synchronization with the internal clock.

However, the inventor has discovered that the above-described transmitter circuit and receiver circuit undesirably has a problem of the complicated circuit configuration and the increased circuit scale, which undesirably cause increased power consumption, due to the architecture in which a clock-embedded signal is transmitted over each transmission channel, and a clock signal is recovered from each transmission channel to allow sampling the data signal with the recovered clock signal.

### SUMMARY

In an aspect of the present invention, a receiver circuit is provided with: a plurality of input terminals; a plurality of hold circuits holding reception signals received by the plurality of input terminals; a detector circuit detecting clock bits from selected one of the reception signals to recover a clock signal in response to the detected clock bits; and a clock circuit connected to the detector circuit and generating one or more internal clock signals from the clock signal. The hold circuits commonly receive the internal clock signal(s) and perform sampling of the reception signals commonly in synchronization with the internal clock signal(s).

Such receiver circuit configuration allows simplification of the circuit configuration of the receiver circuit, since the internal clock signal is generated in response to the clock bit detected from one of the reception signals, and the reception signals are sampled commonly in synchronization with the internal clock signal.

In another aspect of the present invention, a transmitter circuit is provided with: a plurality of output terminals; a clock generator circuit; a plurality of hold circuits commonly connected to the clock generator circuit to receive a plurality of signals, respectively, and to output the plurality of signals in response to a clock signal received from the clock generator circuit; and an output circuit connected to the plurality of hold circuits and outputting transmission signals to the plurality of output terminals, respectively. The output circuit generates one of the transmission signals through selectively incorporating a clock bit into one of the plurality of signals outputted from the plurality of hold circuits.

Such transmitter circuit configuration allows simplification of the circuit configuration of the transmitter circuit, since the clock bit is selectively incorporated into one of the transmission signals.

In still another aspect of the present invention, a data transmission system is provided with: a clock generator circuit; a plurality of output circuits commonly connected to the clock generator circuit and outputting a plurality of transmission signals, respectively, with the transmission signals synchronized with each other; a control circuit connected to one of the plurality of output circuits and incorporating a clock bit into one of the plurality of transmission signals, the one transmission signal being outputted from the one of the plurality of output circuits; a plurality of transmission lines transmitting the transmission signals, respectively; a plurality of input circuits connected with the transmission lines, respectively, and receiving the transmission signals, respectively; and a clock circuit connected to one of the input circuits and detecting a clock bit from the one of the transmission signals to generate an internal clock signal in response to the detected clock bit. The input circuits sample the transmission signals transmitted over the plurality of transmission lines, respectively, commonly in synchronization with the internal clock signal.

Such system configuration allows simplification of the circuit configuration of the data transmission system, since the clock bit is selectively incorporated into one of the transmission signals, and the internal clock signal is generated in response to the clock bit detected from one of the transmission signals, and the transmission signals are sampled commonly in synchronization with the internal clock signal.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram showing an exemplary configuration of an image display apparatus in one embodiment of the present invention;

FIG. 2 is a detailed block diagram showing an exemplary configuration of a transmitter circuit incorporated into an image processing circuit of the image display apparatus shown in FIG. 1;

FIG. 3 is a circuit diagram showing an exemplary configuration of a clock generator circuit incorporated in the transmitter circuit shown in FIG. 2;

FIG. 4 is a block diagram showing an exemplary configuration of a hold circuit (parallel-serial converter circuit) incorporated in the transmitter circuit shown in FIG. 2;

FIG. 5 is a block diagram showing an exemplary configuration of another hold circuit (parallel-serial converter circuit) incorporated in the transmitter circuit shown in FIG. 2;

FIG. 6 is a timing chart showing an exemplary operation of the transmitter circuit incorporated in the image processing circuit shown in FIG. 2;

FIG. 7A is a diagram showing an exemplary data structure of gray-scale data;

FIG. 7B is a timing chart showing the waveform of the signal transmitted over the transmission line;

FIG. 8 is a block diagram showing an exemplary configuration of a receiver circuit;

FIG. 9A is a block diagram showing an exemplary configuration of a hold circuit (serial-parallel converter circuit) incorporated into the receiver circuit shown in FIG. 8;

FIG. 9B is a block diagram showing an exemplary configuration of another hold circuit (serial-parallel converter circuit) incorporated into the receiver circuit shown in FIG. 8;

FIG. 10 is a circuit diagram showing an exemplary configuration of a clock generator circuit incorporated into the receiver circuit shown in FIG. 8;

FIG. 11 is a timing chart showing an exemplary operation of the receiver circuit shown in FIG. 8;

FIG. 12 is a block diagram showing of an exemplary configuration of a transmitter circuit in an alternative embodiment; and

FIG. 13 is a block diagram showing the configuration of a conventional data transmission system.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to embodiments illustrated for explanatory purposes.

### (Overall Configuration)

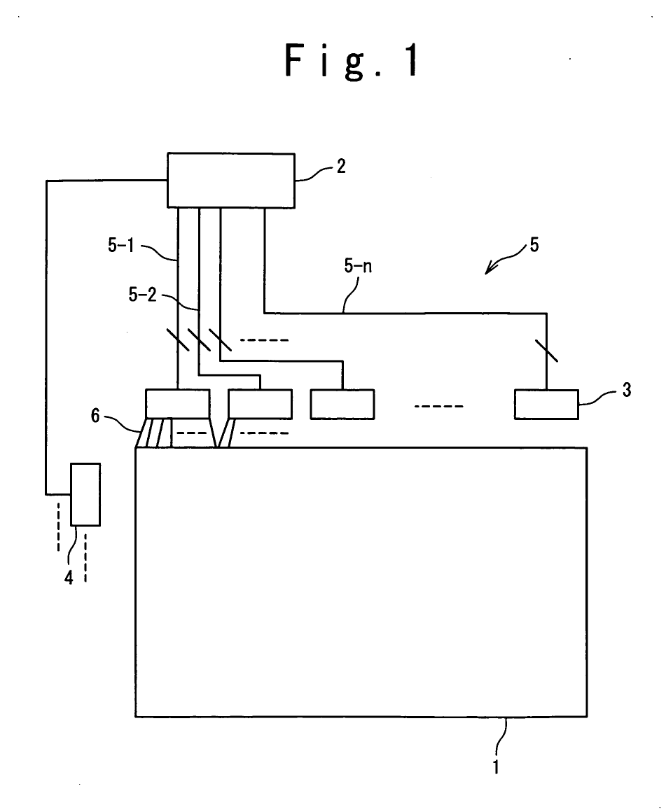

FIG. 1 is an overall schematic view showing an exemplary configuration of an image display apparatus in one embodiment of the present invention, in which a plurality of data line drivers 3 are arranged along an edge of an image display panel 1 to feed drive signals 6 to data lines of the image display panel 1. The brightness or the grayscale level of each pixel is controlled by the drive signals 6 to display a desired image on the image display panel 1. One or more scan control circuits 4 are arrange along another edge of the image display panel 1 to select the rows of the pixels. The data line drivers 3 receive transmission signals carrying grayscale data indicative of the grayscale levels of the respective pixels from an image processing circuit 2 through transmission lines 5. The transmission lines 5 may be also used to transmit control signals, such as a polarity reversal signal indicating the polarity of the drive signals 6, to the data line drivers 3. The transmission lines 5-1 to 5-n are connected between the image processing circuit 2 and the respective data line drivers 3. The transmission lines 5-1 to 5-n each have multiple channels, more specifically, two channels in this embodiment, to address the increase in the amount of data to be transmitted, which is accompanied by the increase in the size and resolution of the image display panel. One channel of each transmission line 5 is used to transmit grayscale data indicating grayscale levels of even-numbered pixels of the image display device 1 and the other channel is used to transmit grayscale data indicating grayscale levels of odd-numbered pixels.

It should be noted that only one data line driver 3 may be provided, when the data line driver 3 is comparable in size to the image display panel 1.

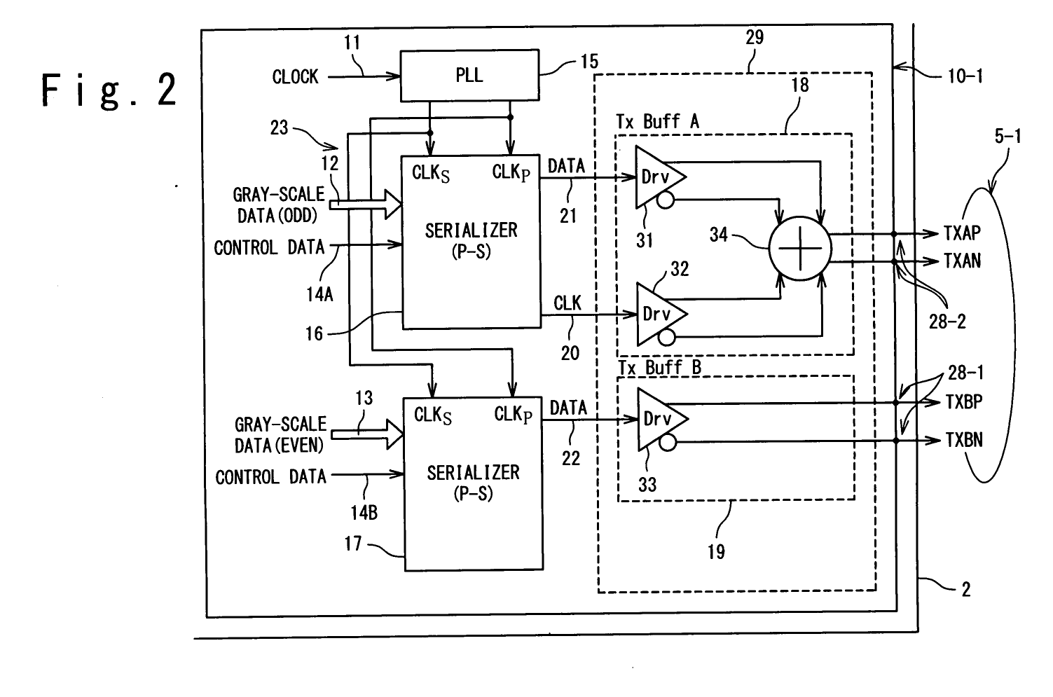

FIG. 2 is a configuration view of the image processing circuit 2. The image processing circuit 2 incorporates transmitter circuits 10-1 to 10-n which are connected with the transmission lines 5-1 to 5-n, respectively. Although FIG. 2 only shows the configuration of the transmitter circuit 10-1, the person skilled in the art would appreciate that the other transmitter circuits 10-2 to 10-n are similarly structured. Each transmission line 5 incorporates multiple channels (two channels in this embodiment as shown in FIG. 2) and each channel includes a pair of signal lines which transmit differential transmission signals, that is, positive-phase and negative-phase signals. More specifically, each transmission line 5 includes positive-phase and negative-phase signal lines TXAP and TXAN for one channel (Channel A) and positive-phase and negative-phase signal lines TXBP and TXBN for the other channel (Channel B).

### (Transmitter Circuit)

The transmitter circuit 10-1 includes a clock generator circuit 15 which receives a clock signal 11 from a clock source (not shown) provided within the image processing circuit 2. A clock generator circuit 15 may be configured as, for example, a PLL (phase locked loop). The clock generator circuit 15 generates a set of clock signals 23 in response to the clock signal 11. The clock signals 23 may be different from each other in the phase and/or frequency. In an alternative embodiment, the clock generator circuit 15 may generate a single clock signal instead of the multiple clock signals 23. In one embodiment, each of the transmitter circuits 10-1 to 10-n may incorporate the clock generator circuit 15. Alternatively, the transmitter circuits 10-1 to 10-n may be commonly connected to a single clock generator circuit 15 to receive the clock signals 23. The clock signals 23 are fed to hold circuits 16 and 17.

The hold circuits 16 and 17 receive grayscale data indicative of grayscale levels of the respective pixels of the image display panel 1 from a processing section (not shown) within the image processing circuit 2. The grayscale data are composed of odd grayscale data 12 indicative of grayscale levels of pixels positioned at odd-numbered positions of the image display panel 1 (hereinafter, referred to as the “odd pixels”) and even grayscale data 13 indicative of grayscale levels of pixels positioned at even-numbered positions of the image display panel 1 (hereinafter, referred to as the “even pixels”). In FIG. 2, the hold circuit 16 receives the odd grayscale data 12 associated with the odd pixels and the hold circuit 17 receives the even grayscale data 13 associated with the even pixels. The hold circuits 16 and 17 also receive various control data 14A and 14B, which may include polarity reversal data for instructing timings of the polarity reversals of the drive signals 6 fed to the pixels and display synchronization data used for generating vertical and horizontal synchronization signals in the data line drivers 3.

The grayscale data 12 and 13 and the control data 14A and 14B may be processed in parallel in the image processing circuit 2. In this case, the hold circuits 16 and 17 are configured as parallel-serial converter circuits which convert the parallel data into serial data or a serial data signal; the hold circuits 16 outputs a serial output signal 21 corresponding to the odd grayscale data 12 and the control data 14A, and the hold circuit 17 outputs a serial output signal 22 corresponding to the even grayscale data 13 and the control data 14B. The hold circuit 16 also outputs a clock signal 20 to be embedded into one of the transmission signals transmitted from the transmitter circuit 10-1 to the corresponding data line driver 3. When the grayscale data 12, 13 and the control data 14A and 14B are fed to the hold circuits 16 and 17 in serial, the hold circuits 16 and 17 may be configured as latch circuits.

The transmitter circuit 10-1 further includes an output circuit 29 which incorporates output buffers 18 and 19 connected to the outputs of the hold circuits 16 and 17, respectively. The outputs of the output buffers 18 and 19 are connected to the output terminals 28-1 and 28-2 of the transmitter circuit 10-1. The output terminals 28-1 are composed of two complementary terminals connected to the complementary signal lines TXBP and TXBN. It should be noted that the two terminals are collectively referred to as the output terminals 28-1, since the two complementary terminals are used to transmit the same data; this also applies to the output terminals 28-2. The output buffer 18 incorporates an amplifier circuit 31 which receives the serial output signal 21 from the hold circuit 16, an amplifier circuit 32 which receives the clock signal 20, and a superposing circuit 34 which superposes the output signals of the amplifier circuits 31 and 32. The outputs of the superposing circuit 34 are connected to the output terminals 28-2 of the transmitter circuit 10-1. The output buffer 19 incorporates an amplifier circuit 33 which receives the serial output signal 22 from the hold circuit 17. The outputs of the amplifier circuit 33 are connected to the output terminals 28-1 of the transmitter circuit 10-1.

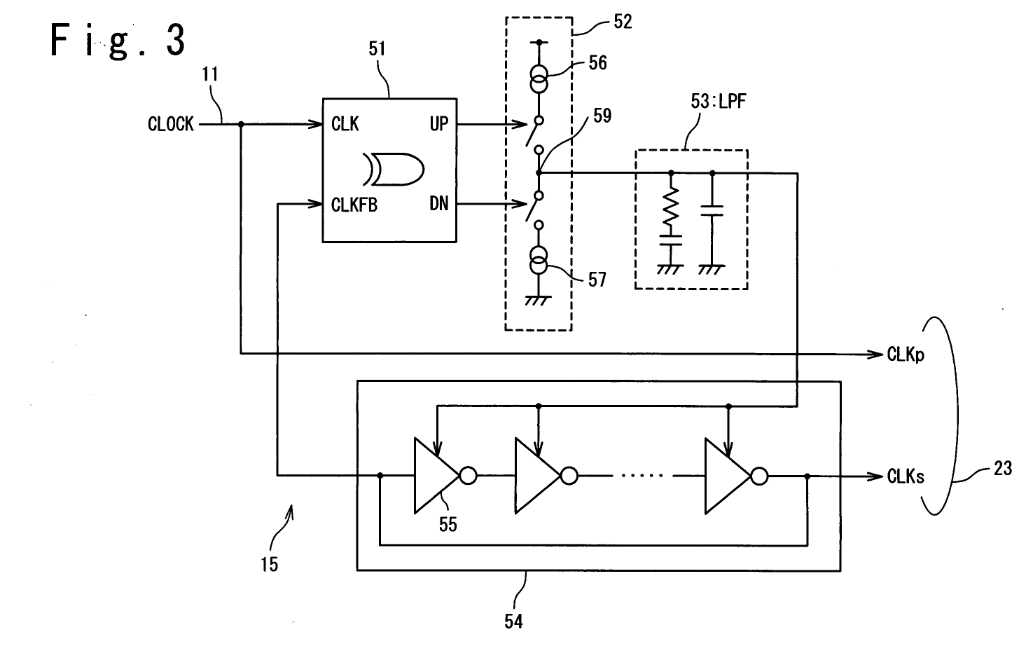

Referring to FIG. 3, which shows details of the clock generator circuit 15, the clock generator circuit 15 includes a phase comparator 51, a charge pump 52, a low pass filter circuit 53 and a voltage controlled oscillator 54. The voltage controlled oscillator 54 incorporates a ring oscillator circuit composed of an odd number of inverters 55 and generates a serial clock signal CLKs of the clock signals 23. The frequency of the serial clock signal CLKs is controlled depending on the power supply voltage applied to the inverters 55. On the other hand, the clock generator circuit 15 outputs the clock signal 11 as a parallel clock signal CLKp of the clock signals 23 as it is.

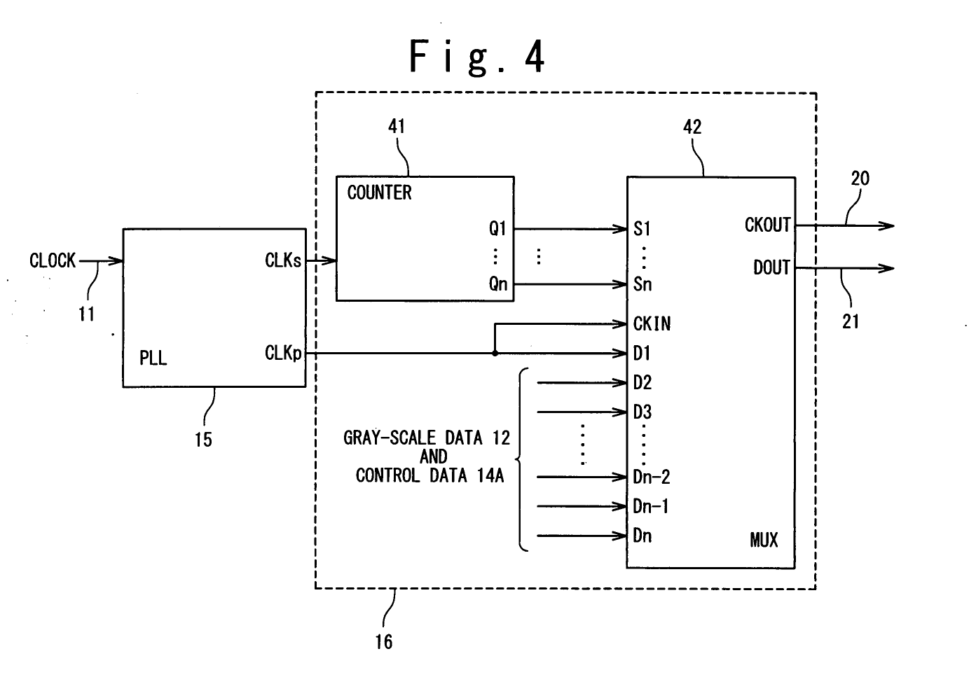

FIG. 4 shows an exemplary configuration of the hold circuit 16 in detail. The hold circuit 16 includes a counter circuit 41 which receives the serial clock signal CLKs and a multiplexer circuit 42 connected to the counter circuit 41. The multiplexer circuit 42 receives the parallel clock signal CLKp, the grayscale data 12 and the control data 14A and outputs the clock signal 20 and the serial output signal 21, which are mentioned above.

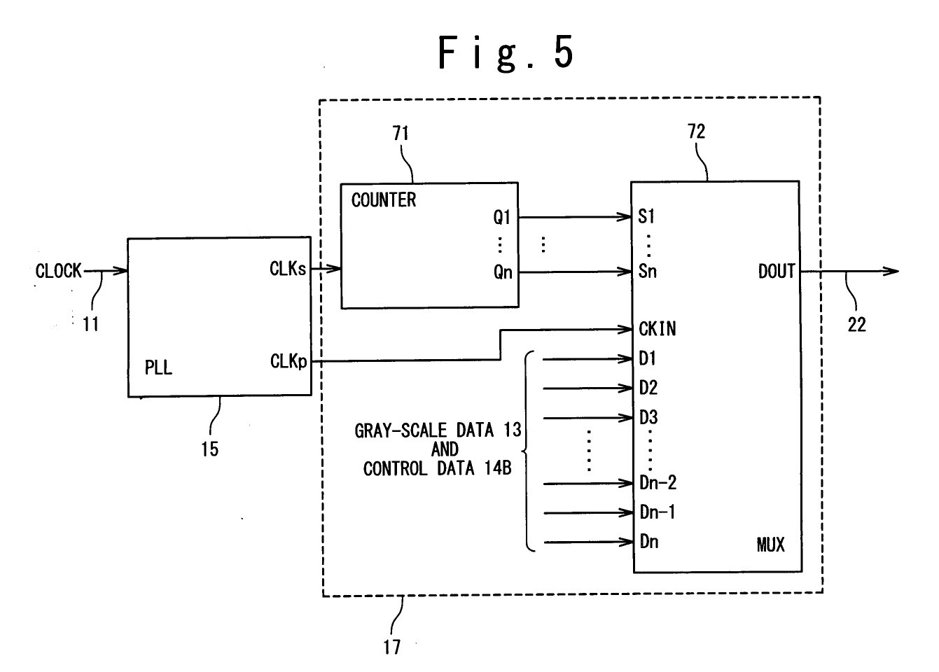

Similarly, FIG. 5 shows an exemplary configuration of the hold circuit 17 in detail. Although both of FIGS. 4 and 5 show the clock generator circuit 15, it should be understood that one clock generator circuit 15 is commonly connected to the hold circuits 16 and 17 in this embodiment; the hold circuits 16 and 17 commonly receive the clock signals 23 from the clock generator circuit 15. The hold circuit 17 includes a counter circuit 71 which receives the serial clock signal CLKs and a multiplexer circuit 72 connected to the counter circuit 41. The multiplexer circuit 72 receives the parallel clock signal CLKp, the control data 14 and the grayscale data 13 and outputs the above-mentioned serial output signal 22.

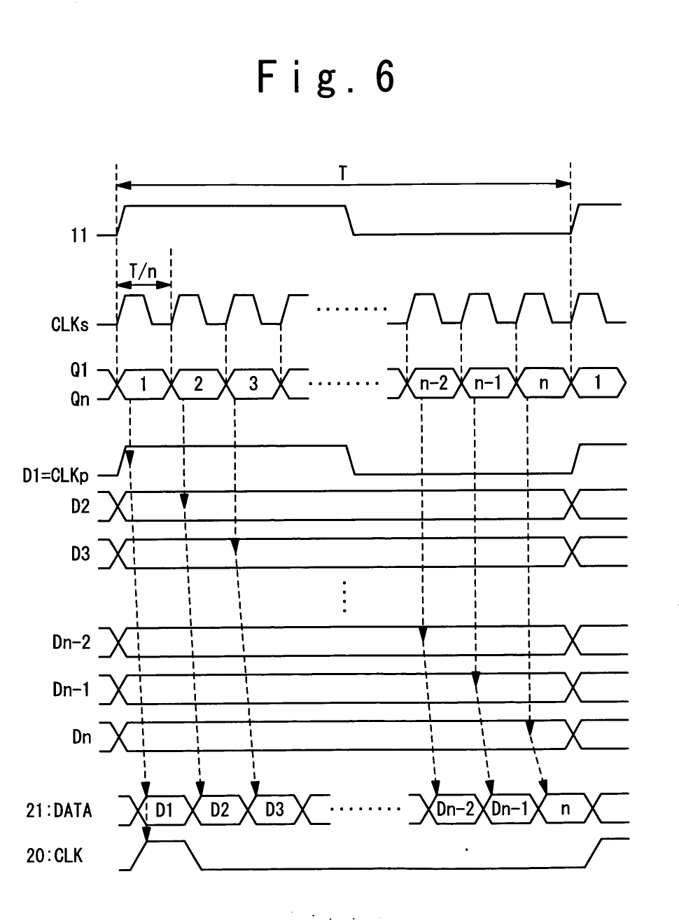

Referring to FIG. 6, which is a timing chart showing waveforms of the relevant signals, an exemplary operation of the transmitter circuit 10-1 will be described below. In the clock generator circuit 15, as shown in FIG. 3, the voltage controlled oscillator 54 operates on the voltage fed from the charge pump 52, which is used as a power supply, and generates the serial clock signal CLKs with a frequency in response to the voltage fed thereto. The serial clock signal CLKs is generated so as to have a frequency approximately a predetermined times, for example, n times (n is a natural number) as large as the frequency of the clock signal 11; in FIG. 6, the symbol “T” indicates the cycle of the clock signal 11, and the cycle of the serial clock signal CLKs is T/n. The phase comparator 51 compares the above-mentioned reference clock signal 11 with the serial clock signal CLKs fed from the voltage controlled oscillator 54, and controls the voltage fed from the charge pump 52 to the voltage controlled oscillator 54. In detail, the voltage level of the output signal UP is raised with the voltage level of the output signal DN lowered in response to the phase difference between the clock signal 11 and the serial clock signal CLKs, for example, when the phase of the serial clock signal CLKs is advanced from that of the clock signal 11. As a result, the charge pump circuit 52 decreases or blocks the current flowing from a current source 56 to an output node 59, or increases the current pulled out from the output node 59 by a current source 57, thereby lowering the output voltage. The output voltage of the charge pump 52 is filtered by the filter circuit 53, which incorporates a resistor element and capacitor elements, to remove noise, and the noise-removed output voltage is fed to the voltage controlled oscillator 54 to lower the reversal frequency of the respective inverters 55, thereby delaying the phase of the serial clock signal CLKs generated by the voltage controlled oscillator 54. Similarly, the phase of the serial clock signal CLKs is advanced when the phase of the serial clock signal CLKs is delayed from that of the clock signal 11. As a result, the clock generator circuit 15 generates the serial clock signal CLKs with the n-times frequency of the clock signal 11 in synchronization with the clock signal 11. The clock generator circuit 15 also outputs the clock signal 11 as the parallel clock signal CLKp.

As shown in FIG. 4, the serial clock signal CLKs is supplied to the counter circuit 41 in the hold circuit 16. The counter circuit 41 receives and counts the serial clock signal CLKs, and sequentially and repeatedly activates the output signals Q1 to Qn in synchronization with the serial clock signal CLKs. As a result, each of the output signals Q1 to Qn has a pulse width of T/n, which is the cycle of the serial clock signal CLKs, and a cycle of T, which is n times as large as the cycle of the serial clock signal CLKs. The output signals Q1 to Qn are generated so that the phases thereof are different from one another. In FIG. 6, the numbers in the boxes denoted by the notation “Q1-Qn” indicate which of the n output signals Q1 to Qn is activated. The output signals Q1 to Qn are fed to the selection control inputs S1 to Sn of the multiplexer circuit 42. As described later, the output signals Q1 to Qn are used to select data bits fed to the data inputs D1 to Dn.

The multiplexer circuit 42 additionally receives the parallel clock signal CLKp on the data input D1, while receiving the grayscale data 12 and the control data 14A on the data inputs D2 to Dn. In this embodiment, the control data 14A are fed to the data inputs D2 to D4. In an alternative embodiment, only the grayscale data 12 may be fed to the data inputs D2 to Dn in a case where there is not sufficient room in the throughput of the image processing circuit 2 and the band of the transmission lines 5. In synchronization with the parallel clock signal CLKp fed to the clock input CKIN, the grayscale data 12 and the control data 14 are simultaneously latched into the multiplexer circuit 42 and sequentially outputted from the common output DOUT in accordance with the selection by the output signals Q1 to Qn of the counter circuit 41. As a result, as indicated by the broken lines in FIG. 6, the parallel clock signal CLKp, the grayscale data 12 and the control data 14A are converted into the serial output signal 21.

It should be noted that the parallel clock signal CLKp is inputted onto the data input D1, which corresponds to the data bits of the serial output signal 21 selected by the counter output signal Q1, in the operation shown in FIG. 6. This aims to avoid data bits of data to be transmitted, such as data bits of the grayscale data 12 and the control data 14A, being incorporated into the invalid positions of the serial output signal 21 to which the clock signal 20 is to be superposed by the output buffer 18 at the next stage; the data bits inputted to the data input D1 are lost in the output buffer 18 in superposing the clock signal 20 into the serial output signal 21. Therefore, data bits to be transmitted should not be fed to the data input D1. This implies that the parallel clock signal CLKp need not to be fed to the data input D1; the data input D1 may be fixed to any of the high or low level.

In addition, the multiplexer circuit 42 outputs the output signal Q1 received from the counter circuit 41 as the clock signal 20.

The operation of the hold circuit 17 is similar to that of the hold circuit 16. As shown in FIG. 5, the serial clock signal CLKs is supplied to a counter circuit 71 in the hold circuit 17. The counter circuit 71 operates similarly to the counter circuit 41, generating the output signals Q1 to Qn. The waveforms of the output signals Q1 to Qn generated by the counter circuit 71 are identical to those of the output signals Q1 to Qn generated by the counter circuit 41. The output signals Q1 to Qn are fed to the selection control inputs S1 to Sn of the multiplexer circuit 72.

The multiplexer circuit 72 receives the even grayscale data 13 and the control data 14B on the data inputs D2 to Dn. In this embodiment, the control data 14B are fed to the data input D1 to D4. Differently from the multiplexer circuit 42, as shown in FIG. 5, the multiplexer circuit 72 receives the control data 14B on the data input D1. In an alternative embodiment, data bits of the grayscale data 13 may be fed to the data input D1. It should be noted that the multiplexer circuit 72 is not designed to output a clock signal, while the multiplexer circuit 42 is designed to output the output signal Q1 received from the counter circuit 41 as the clock signal 20. The other configuration and operation of the multiplexer circuit 72 are same as those of the multiplexer circuit 42. Although no timing chart showing the waveforms of the input and output signals of the multiplexer circuit 72 is given, those skilled in the art would appreciate that the multiplexer circuit 72 operates in the similar way to the multiplexer circuit 42 shown in FIG. 6. The multiplexer circuit 72 is different from the multiplexer circuit 42 in that the control data 14B are fed to the data input D1 in place of the parallel clock signal CLKp and that there is not an output corresponding to the clock signal 20.

As shown in FIG. 2, the serial output signal 21 and the clock signal 20 generated by the hold circuit 16 are fed to the driver circuits 31 and 32 of the output buffer 18, respectively, and subjected to amplification and/or impedance conversion to generate a pair of complementary signals. The driver circuit 32 is configured to generate the complementary signals with a different signal level from that of the complementary signals generated by the driver circuit 31. In one embodiment, the signal level of the complementary signals outputted from the driver circuit 32 is adjusted to be larger than that of the complementary signals outputted from the driver circuit 31. Alternatively, the signal level of the complementary signals outputted from the driver circuit 32 may be adjusted to be smaller than that of the complementary signals outputted from the driver circuit 31. The output signal level control of the driver circuits 31 and 32 may be achieved by controlling the power supply voltages fed to the driver circuits 31 and 32.

The superposing circuit 34 superposes the clock signal 20 amplified by the driver circuit 32 onto the serial output signal 21 amplified by the driver circuit 31 to develop a pair of complementary transmission signals on the signal lines TXAP and TXAN. Specifically, the superposing circuit 34 superposes the output signals from the driver circuits 31 and 32 and outputs the resultant complementary signals to the signal lines TXAP and TXAN through the output terminals 28-2. It should be noted that the superposing circuit 34 is selectively provided only in the output buffer 18 out of the output buffers 18 and 19. This allows the superposing circuit 34 to be formed by merely connecting the outputs of the driver circuits 31 and 32 so that the outputs on which the complementary output signals with the same polarity are connected, enhancing the simplification in the circuit configuration used to superpose the clock signal. In this case, the output of the driver circuit 31 is set high impedance while the serial output signal 21 is not outputted and the driver circuit 32 is set high impedance while the clock signal 20 is not outputted.

In an alternative embodiment, the superposing circuit 34 may be controlled by a control circuit (not shown) to select the driver circuits 31 and 32 in response to the clock signal 20. The selected one of the driver circuits 31 and 32 is connected to the output terminals 28-2 to allow outputting the complementary output signals therefrom. Such configuration, which requires providing a selecting mechanism, such as a control circuit and a switch circuit for switching the driver circuits 31 and 32, only for the output buffer 18, also allows enhancing the simplification in the circuit configuration used to superpose the clock signal. In this case, it is not necessary to set the driver circuits 31 and 32 to the high impedance state as described above.

On the other hand, the serial output signal 22 generated by the hold circuit 17 is fed to the driver circuit 33 of the output buffer 19 and subjected to amplification and/or impedance conversion, and the resultant complementary transmission signals are outputted to the signal lines TXBP and TXBN through the output terminals 28-1. Although no clock signal is superposed on the complementary transmission signals developed on the signal lines TXBP and TXBN, the transmission signals developed on the signal lines TXBP and TXBN are substantially synchronized with the transmission signals on the signal lines TXAP and TXAN, since the hold circuits 16 and 17 are synchronized with each other by the clock signals 23 commonly received from the clock generator circuit 15.

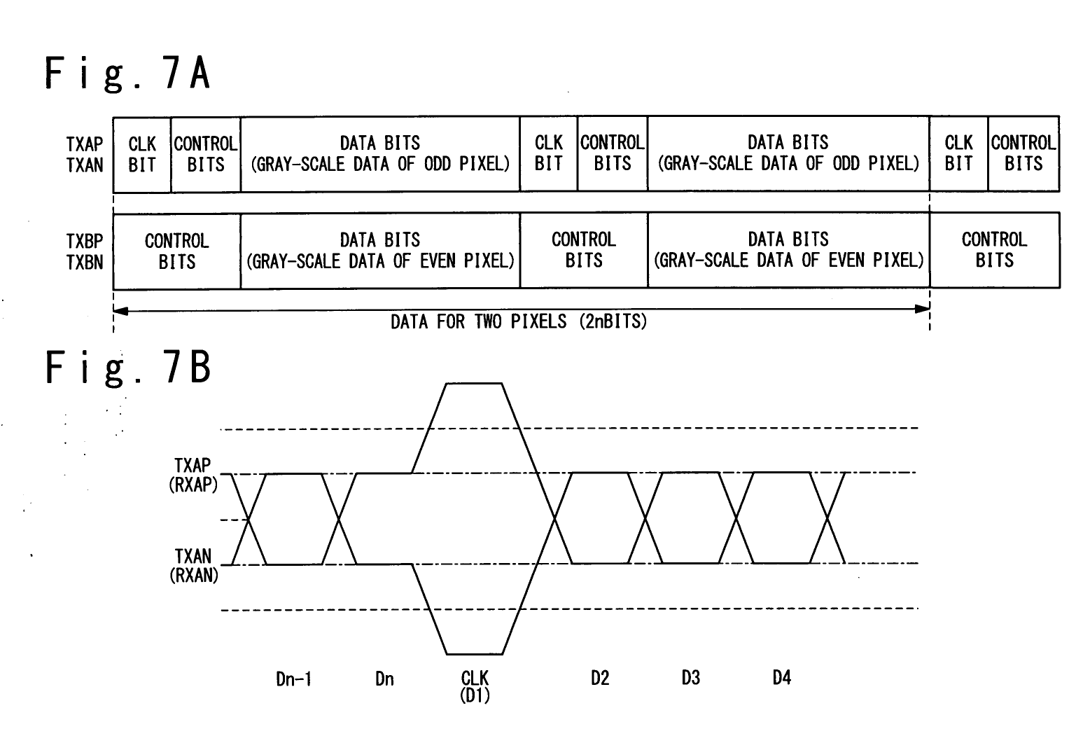

FIG. 7A is a schematic view showing an exemplary data arrangement of the transmission signals transmitted over the signal lines TXAP and TXAN and the signal lines TXBP and TXBN. In this example, the clock signal 20 is superposed or embedded into the transmission signals transmitted over the signal lines TXAP and TXAN twice for grayscale data of two odd pixels, and the transmission signals transmitted over the signal lines TXAP and TXAN additionally carry the control data 14A, such as the polarity reversal data, in addition to the odd grayscale data 12.

In detail, the data carried by the transmission signals transmitted over the transmission lines TXAP and TXAN incorporate: two clock bits, a set of control bits, and the grayscale data 12 for two odd pixels; it should be noted that the control bits are data bits of the control data 14A. The clock bits are generated by superposing the clock signal 20 into the transmission signals, and used for the clock recovery in the data line drivers 3.

FIG. 7B is a timing chart showing the waveforms of the transmission signals transmitted over the signal lines TXAP and TXAN. The clock signal is superposed on the positions in the time domain where the data bits fed to the data input D1 are located. As shown in FIG. 7B, the amplitudes of the transmission signals transmitted over the signal lines TXAP and TXAN at the positions corresponding to the clock bits are different from those at other positions; FIG. 7B shows a case where the amplitudes of the transmission signals transmitted over the signal lines TXAP and TXAN are selectively increased at the positions where the clock signal 20 is superposed, that is, the positions where the clock bits are located. Immediately after a clock bit is transmitted, a data bit fed to the data input D2 is transmitted.

In one embodiment, one or more dummy bits may be transmitted immediately after each clock bit is transmitted. The amplitudes of the transmission signals transmitted over the signal lines TXAP and TXAN at the positions corresponding to the clock bits are different form those at other positions, and this may cause instability in the voltage levels of the signal lines. Such instability may cause bit errors when effective data (such as the control bits and the grayscale data) are transmitted immediately after the clock bits are transmitted. The transmission of the dummy bits effectively improves the reliability in transmitting the effective data.

It is also preferable that the transmission signals transmitted over the signal lines TXAP and TXAN are generated so that the polarities of the transmission signals at the positions corresponding to the clock bits are same as those of the transmission signals at the positions corresponding to the data bits just previously transmitted, and that the amplitudes of the transmission signals at the positions corresponding to the clock bits are larger than those at the positions corresponding to the data bits just previously transmitted. This avoids abrupt changes in the voltage levels of the signal lines TXAP and TXAN, thereby reducing noise.

On the other hand, the transmission signals transmitted over the signal lines TXBP and TXBN do not incorporate clock bits, while transmitting the even grayscale data 13 of the even pixels in the image display panel 1; no clock signal is superposed on the transmission signals transmitted over the signal lines TXBP and TXBN. In addition to the even grayscale data 13, the data transmitted over the signal lines TXBP and TXBN include the control data 14B, such as the polarity reversal data. The positions of the control data 14B in the transmission signals transmitted over the signal lines TXBP and TXBN may be same as those of the clock bits transmitted over the signal lines TXAP and TXAN in the time domain, or positions immediately after the clock bits are transmitted. This effectively improves the efficiency of internal signal processing both on the transmitting and receiving sides.

In an alternative embodiment, two clock bits may be incorporated in the transmission signals for each pixel. In another alternative embodiment, one clock bit may be superposed for each data bit of the data to be transmitted, when there is sufficient room in the band width of the signal lines.

### (Receiver Circuit)

Next, a description is given of an exemplary configuration and operation of receiver circuits which receive the transmission signals transmitted over the signal lines TXAP and TXAN and the signal lines TXBP and TXBN. In the following description, which is directed to the receiving side, the signal lines TXAP, TXAN, TXBP and TXBN are referred to as the signal lines RXAP, RXAN, RXBP and RXBN, respectively, and the transmission signals transmitted over the signal lines TXAP, TXAN, TXBP and TXBN are referred to as the reception signals. It is desirable that the transmission line composed of the signal lines TXAP and TXAN and the transmission line composed of the signal lines TXBP and TXBN are disposed close to each other to reduce the difference in the delay time, preferably below the pulse width of the transmission signals transmitted over the signal lines TXAP, TXAN, TXBP and TXBN. Such requirement is usually satisfied in a case when interrelated data, such as grayscale data for the even pixels and odd pixels, are transmitted over transmission lines disposed close to each other from the image processing circuit 2 to the data line drivers 3.

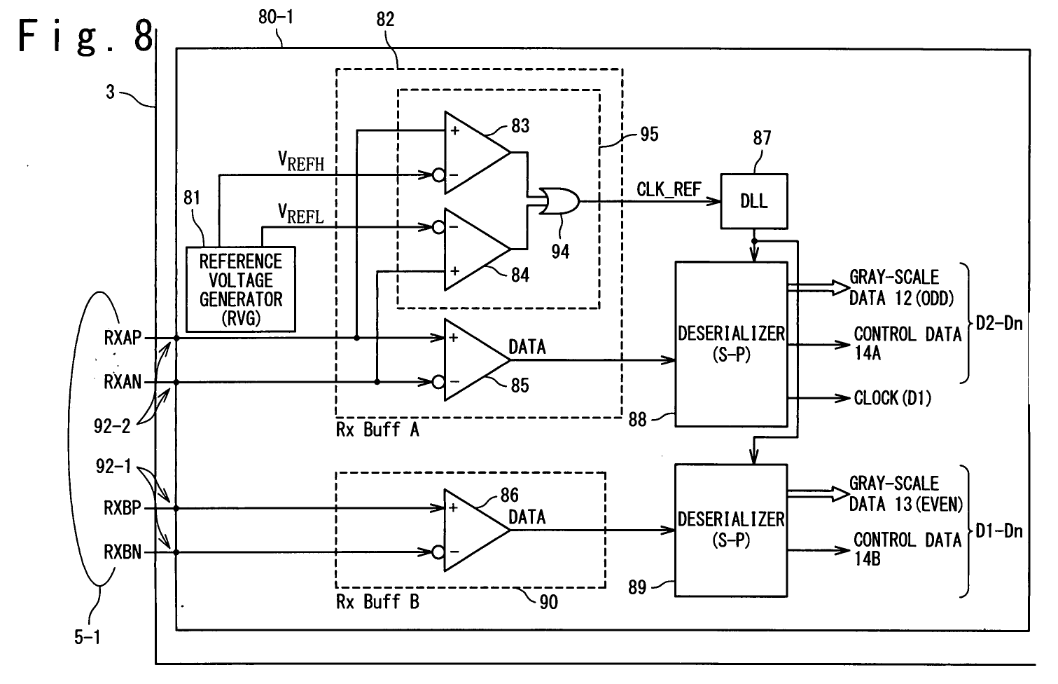

FIG. 8 is circuit diagram showing an exemplary configuration of the data line drivers 3. The data line drivers 3 are connected to the transmission lines 5-1 to 5-n, respectively, and provided with receiver circuits 80-1 to 80-n. Shown in FIG. 8 is the configuration of the data line driver 3 connected to the transmission line 5-1, which incorporates the receiver circuit 80-1. The input terminals 92-1 of the receiver circuit 80-1 are connected to the signal lines RXBP and RXBN and the input terminals 92-2 are connected to the signal lines RXAP and RXAN of the transmission line 5-1. The input terminals 92-1 are composed of two complementary terminals connected to the complementary signal lines. Since the two complementary terminals are used to receive the same data, these two terminals are collectively referred as the input terminals 92-1. This also applies to the input terminals 92-2.

The receiver circuit 80-1 includes a receiving buffer 90 connected to the input terminals 92-1, a receiving buffer 82 connected to the input terminals 92-2, a reference voltage generator circuit 81 connected to the receiving buffer 82, a clock generator circuit 87 and hold circuits 88 and 89 which hold the received data. The receiving buffer 90 includes an amplifier 86 which compares the voltage levels on the signal lines RXBP and RXBN connected to the input terminals 92-1 to generate an internal data signal in response to the result of the voltage level comparison. The receiving buffer 82, on the other hand, includes an amplifier 85 and a detector circuit 95. The amplifier 85 compares the voltage levels of the signal lines RXAP and RXAN to generate another internal data signal in response to the result of the voltage level comparison. The detector circuit 95 extracts the clock bits from the reception signals transmitted over the signal lines RXAP and RXAN. In detail, the detector circuit 95 incorporates a pair of amplifiers 83 and 84 for detecting the voltage levels on the signal lines RXAP and RXAN, respectively, and an OR circuit 94 connected to the outputs of the amplifiers 83 and 84. The output of the OR circuit 94 is connected to the clock generator circuit 87. As described below, a clock signal CLK_REF is generated on the output of the OR circuit 94.

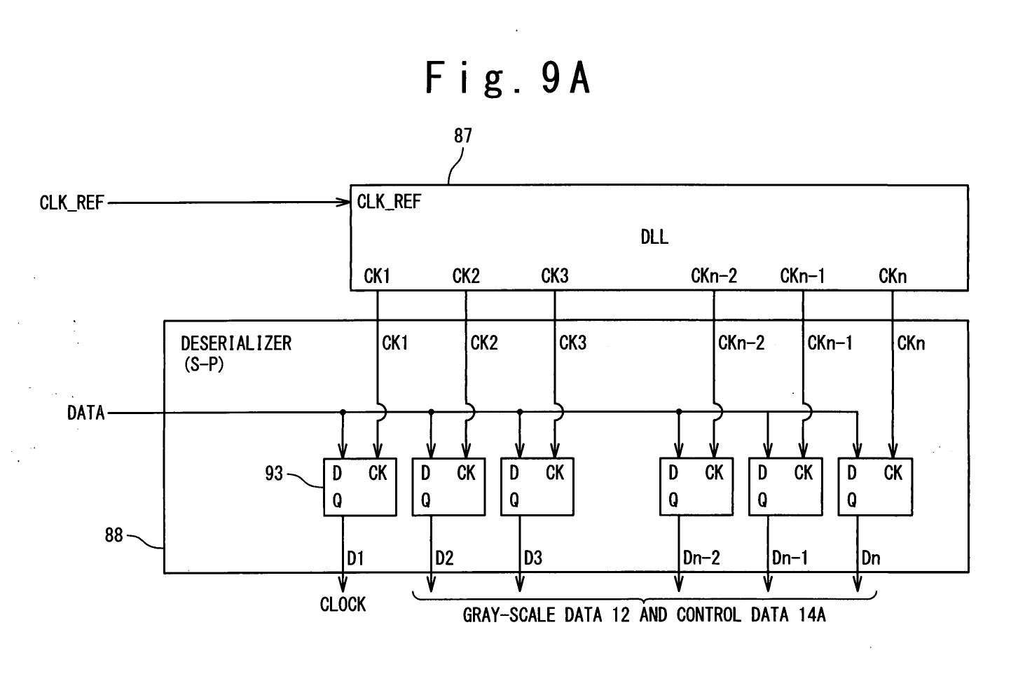

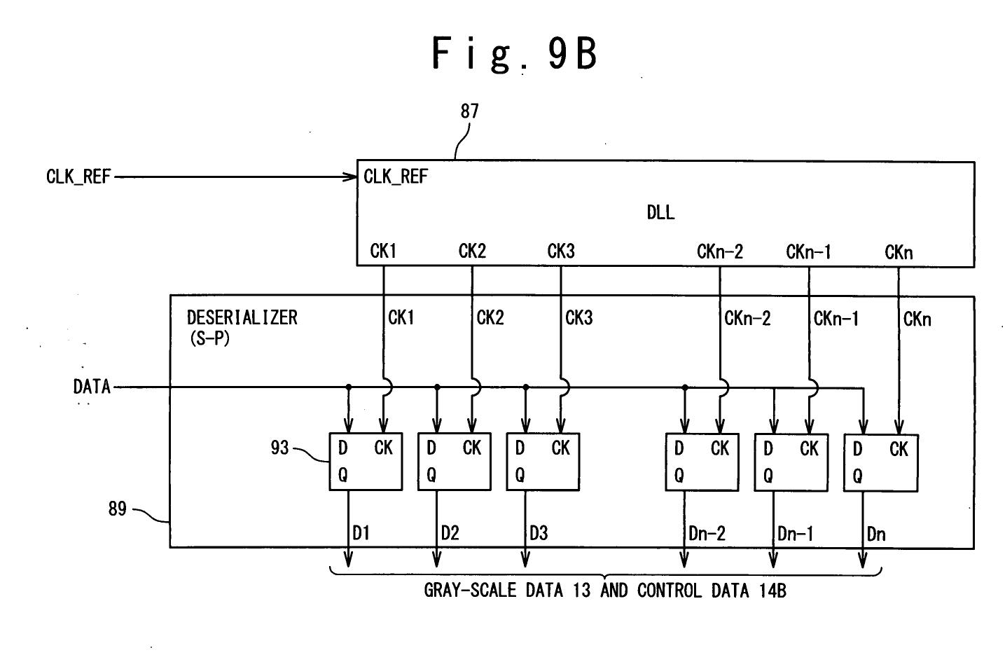

FIG. 9A is a detailed block diagram showing an exemplary configuration of the hold circuit 88. The clock generator circuit 87 receives the clock signal CLK_REF from the detector circuit 95 and generates internal clock signals CK1 to CKn. The internal clock signals CK1 to CKn are supplied to the hold circuit 88. The hold circuit 88 includes n flip-flop circuits 93. Each flip-flop circuit 93 has a data input terminal D, a clock input terminal CK and a data output terminal Q. The flip-flop circuits 93 commonly receive the internal data signal from the amplifier 85 and also receive corresponding ones of the internal clock signals CK1 to CKn from the clock generator circuit 87 to generate output signals on the data outputs D1 to Dn, respectively.

As shown in FIG. 9B, the hold circuit 89 is similarly structured. The internal clock signals CK1 to CKn are supplied to the hold circuit 89 from the clock generator circuit 87. The hold circuit 89 includes n flip-flop circuits 93. The flip-flop circuits 93 commonly receive the internal data signal from the amplifier 86 and also receive corresponding ones of the internal clock signals CK1 to CKn from the clock generator circuit 87 to generate output signals on the data outputs D1 to Dn, respectively.

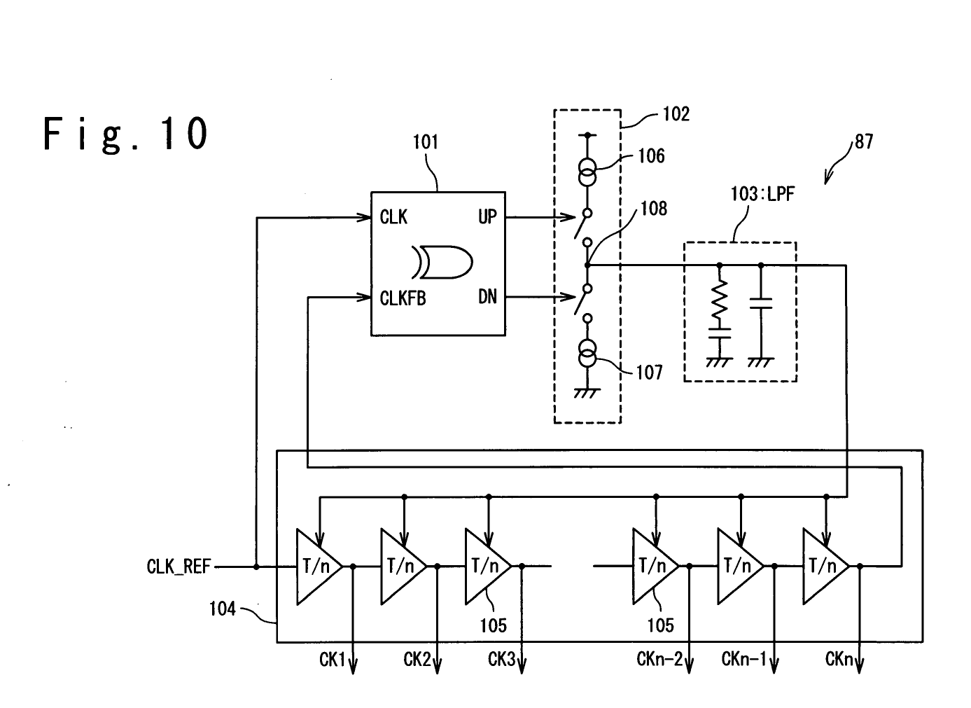

FIG. 10 is a detailed circuit diagram showing an exemplary configuration of the clock generator circuit 87. In one embodiment, the clock generator circuit 87 is configured as a DLL (delay locked loop) circuit. The clock generator circuit 87 includes a phase comparator 101, a charge pump 102, a filter circuit 103 and a voltage controlled delay circuit 104 incorporating serially connected delay circuits 105. Each delay circuit 105 has a delay time of T/n.

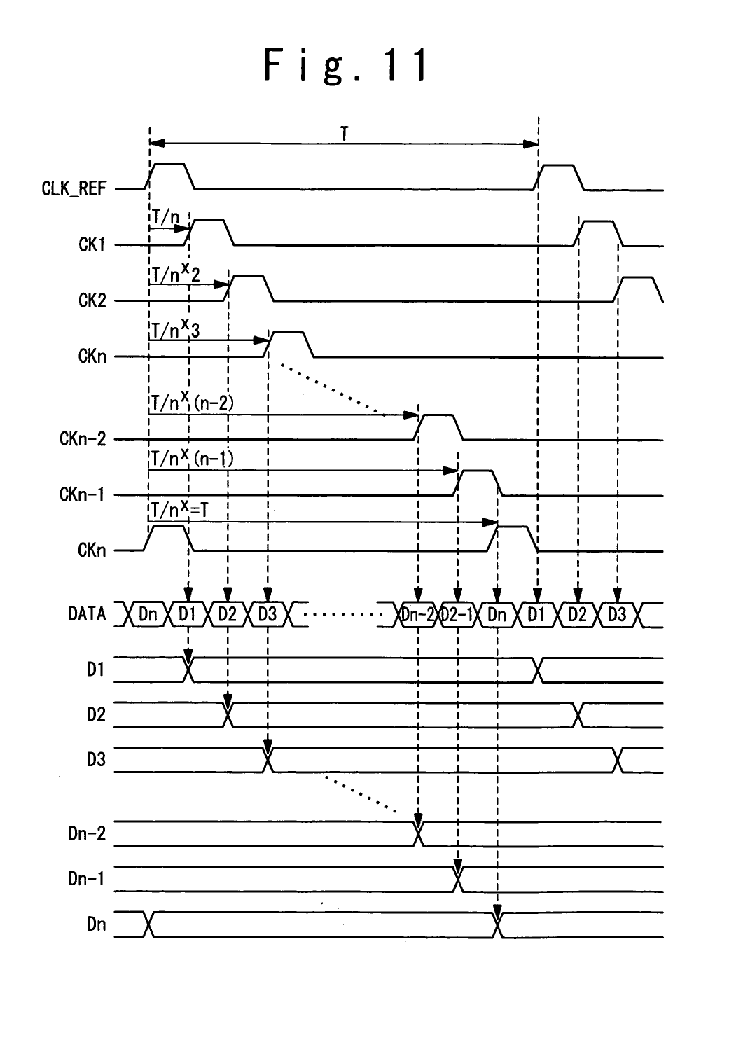

Next, referring to a timing chart of FIG. 11, an operation of the receiver circuit 80-1 will be described. The reference voltage generating circuit 81 generates a pair of reference voltages V_{REFH} and V_{REFL}, and feeds the reference voltages V_{REFH} and V_{REFL} to the amplifiers 83 and 84, respectively. The reference voltages V_{REFH} and V_{REFL} are higher than the voltage level to which the reception signals on the signal lines RXAP and RXAN are driven when the reception signals on the signal lines RXAP and RXAN are set to the high level for the effective data (the control data and the grayscale data 12), and lower than the voltage level to which the reception signals on the signal lines RXAP and RXAN are driven when the reception signals on the signal lines RXAP and RXAN are set to the high level for the clock bits.

Referring back to FIG. 8, when the reception signal on the signal line RXAP is pulled up to the high level for a clock bit incorporated therein and the reception signal on the signal line RXAN is pulled down to the low level for the clock bit, the voltage level of the non-inverting input of the amplifier 83 connected to the signal line RXAP is raised above that of the inverting input of the amplifier 83. As a result, the output of the amplifier 83 is pulled up to the high level. When the reception signal on the signal line RXAP is pulled down to the low level for a clock bit incorporated therein and the reception signal on the signal line RXAN is pulled up to the high level for the clock bit, on the other hand, the voltage level of the non-inverting input of the amplifier 84 connected to the signal line RXAN is raised above that of the inverting input of the amplifier 84. As a result, the output of the amplifier 84 is pulled up to the high level. Since the outputs of the amplifiers 83 and 84 are connected to the OR circuit 94, the detector circuit 95 successfully detect the clock bits incorporated and the clock signal CLK_REF is successfully recovered and outputted from the OR circuit 94, regardless of whether the clock bits are incorporated as the positive or negative phase in the reception signals. FIG. 11 shows the waveform of the recovered clock signal CLK_REF.

As described above with regard to the transmitter circuit 10-1, the amplitudes of the reception signals on the signal lines RXAP and RXAN at the positions corresponding to the clock bits may be smaller than those at the positions corresponding to the grayscale data and control data. In this case, the configuration of the receiver circuit is modified as follows: The reference voltage generator circuit 81 is replaced with a reference voltage generator circuit which generates reference voltages V1 and V2, and the detector circuit 95 is replaced with another detector circuit differently configured. The reference voltage V1 is set lower than the voltage level of the reception signals at the positions corresponding to the clock bits, and the reference voltage V2 is set higher than the voltage level of the reception signals at the positions corresponding to the clock bits and lower than the voltage level of the reception signals at the positions corresponding to the effective data (the control data and grayscale data). The detector circuit includes a pair of amplifiers and an AND circuit, one detecting that the voltage level of the signal line RXAP is higher than V1 and the other detecting that the voltage level of the signal line RXAP is lower than V2. Then, the logical AND of the detection results of the amplifiers is obtained by the AND circuit and the output signal of the AND circuit is used as the clock signal CLK_REF. The same circuitry is provided for the signal line RXAN to address both of the cases when the clock bits are incorporated as the data bits of the positive or phase or the negative phase in the positive and negative phases.

The clock signal CLK_REF is fed to the clock generator circuit 87 as shown in FIG. 10. In the clock generator circuit 87, the clock signal CLK_REF is delayed in stages by serially-connected delay circuit 105 to generate a set of internal clock signals CK1 to CKn. The phase comparator 101 compares the phase of the internal clock signal CKn with the phase of the clock signal CLK_REF. When the phase of the internal clock signal CKn is advanced in the time domain from the phase of the clock signal CLK_REF, for example, the voltage level of an output signal UP is lowered and the voltage level of an output signal DN is raised. As a result, the charge pump circuit 102 decreases or blocks the current flowing from a current source 106 to the output node 108, alternatively, increases the current pulled out from the output node 108 by a current source 107 in response to the output signals, to thereby lower the output voltage of the charge pump 102. The output voltage of the charge pump 102 is filtered by a filter circuit 103 to remove noise, and the noise-removed output voltage is supplied to the delay circuit 105 to decrease the signal transmission rate therein. This results in delaying the phases of the internal clock signals CK1 to CKn. The phases of the internal clock signals CK1 to CKn are similarly controlled also in the case when the phase of the internal clock signal CKn is delayed in the time domain from the phase of the clock signal CLK_REF. In this way, the clock generator circuit 87 generates the set of multi-phased internal clock signals CK1 to CKn using the clock signal CLK_REF as the reference. The internal clock signals CK1 to CKn form a set of pulse signals phased at the phase intervals of T/n; the waveforms of the internal clock signals CK1 to CKn are shown in FIG. 11.

On the other hand, the amplifier circuit 85 shown in FIG. 8 compares the voltages levels on the input terminals 92-2 to detect data on the signal lines RXAP and RXAN, and generates an internal data signal DATA indicative of the detected data. The generated internal data signal DATA is fed to the hold circuit 88.

As shown in FIG. 9, the hold circuit 88 supplies the internal data signal DATA to each of n flip-flop circuits 93 and also supplies the internal clock signals CK1 to CKn to the flip-flop circuits 93, respectively. Thereby, the data bits of the reception signals serially received at the input terminals 92-2 are stored in the n flip-flop circuits 93 as shown in FIGS. 9A and 11, and outputted from the data outputs D1 to Dn in parallel. It should be noted that the data output D1 of the hold circuit 88 corresponds to the clock signal 20 superposed on the reception signals transmitted over the signal lines RXAP and RXAN; and data bits outputted from the data output D1 are not effective data. Therefore, the output signal outputted from the data output D1 may be dealt as an output clock signal CLOCK in subsequent signal processing in the data line driver 3. Alternatively, any of the above-mentioned internal clock signals CK1 to CKn, for example, the internal clock signal CKn may be outputted as the output clock signal CLOCK. FIG. 8 shows the case when selected one of the internal clock signals CK1 to CKn is used as the output clock signal CLOCK.

It should be noted that the serially-connected flip-flop circuits 93 operate as a serial-parallel converter circuit operating in synchronization with the internal clock signals CK1 to CKn. The data outputted in parallel from the data outputs D2 to Dn of the hold circuit 88 are the reproductions of the data fed to the data inputs D2 to Dn of the hold circuit 16 in the transmitter circuit 10-1, specifically, the grayscale data 12 of the odd pixels and the control data 14A as shown in FIGS. 8 and 9A. In an alternative embodiment, as described with regard to the transmitter circuit, the data outputted in parallel from the data outputs D1 to Dn may include only the grayscale data 12 control data, if there is not sufficient room in the capacities of the processing circuits and transmission lines.

Referring back to FIG. 8, the amplifier circuit 86 compares the voltage levels of the input terminals 92-1 to detect the data transferred over the signal lines RXBP and RXBN, and generates an internal data signal DATA indicative of the detected data. The internal data signal DATA is fed to the hold circuit 89. The hold circuit 89 has the same configuration as the hold circuit 88. The hold circuits 88 and 89 are commonly connected to the clock generator circuit 87 and receive the same internal clock signals CK1 to CKn. In the hold circuit 89, as shown in FIG. 9B, the internal data signal DATA is commonly supplied to the n flip-flop circuits 93 and the internal clock signals CK1 to CKn are supplied to the flip-flop circuits 93, respectively. Thereby, the data bits of the reception signals serially received by the input terminals 92-1 are stored in the n flip-flop circuits 93, and outputted from the data outputs D1 to Dn, respectively, as shown in FIGS. 9B and 11. It should be noted that, differently from the case of the hold circuit 88, the data bits of the control data 14B transmitted over the signal lines RXBP and RXBN are outputted from the data output D1 of the hold circuit 89, and used in the subsequent processing in the data line driver 3 in the same way as the grayscale data 13 and the control data 14B outputted from the data outputs D2 to Dn. This implies that the set of flip-flop circuits 93, including the flip-flop circuit 93 fed with the internal clock signal CK1, operates as a serial-parallel converter circuit. The data outputted in parallel from the data outputs D1 to Dn of the hold circuit 89 are the reproductions of the grayscale data 13 and the control data 14B fed to the data inputs D1 to Dn of the hold circuit 17 in the transmitter circuit 10-1. As described with regard to the transmitter circuit, only the grayscale data 13 may be fed to all of the data inputs D1 to Dn of the hold circuit 17 and reproduced on the corresponding data outputs D1 to Dn of the hold circuit 89, if there is not sufficient room in the capacities of the processing circuits and transmission lines.

In summary, the receiver circuit 80-1 in this embodiment is designed to detect the clock signal superposed into the transmission signals (or the clock bits) transmitted over the transmission lines only on the input terminals 92-2, and to use the resultant clock signal CLK_REF and the internal clock signals CL1 to CLn generated therefrom for the reception and serial-parallel conversion of the transmission signals received by both of the input terminals 92-1 and 92-2. This effectively allows simplification and size reduction of the receiver circuit configuration, while effectively reducing the power consumption of the receiver circuit 80-1. The use of the receiver circuit of this embodiment in portable display devices effectively helps miniaturization and power consumption reduction of the portable display devices.

In addition, as described above, the transmitter circuit configuration of this embodiment effectively achieves miniaturization and power consumption reduction of the transmitter circuit. This means that the use of both of the transmitter circuit and receiver circuit of this embodiment is especially effective for portable devices.

It is apparent that the present invention is not limited to the above embodiments, but may be modified and changed without departing from the scope of the invention.

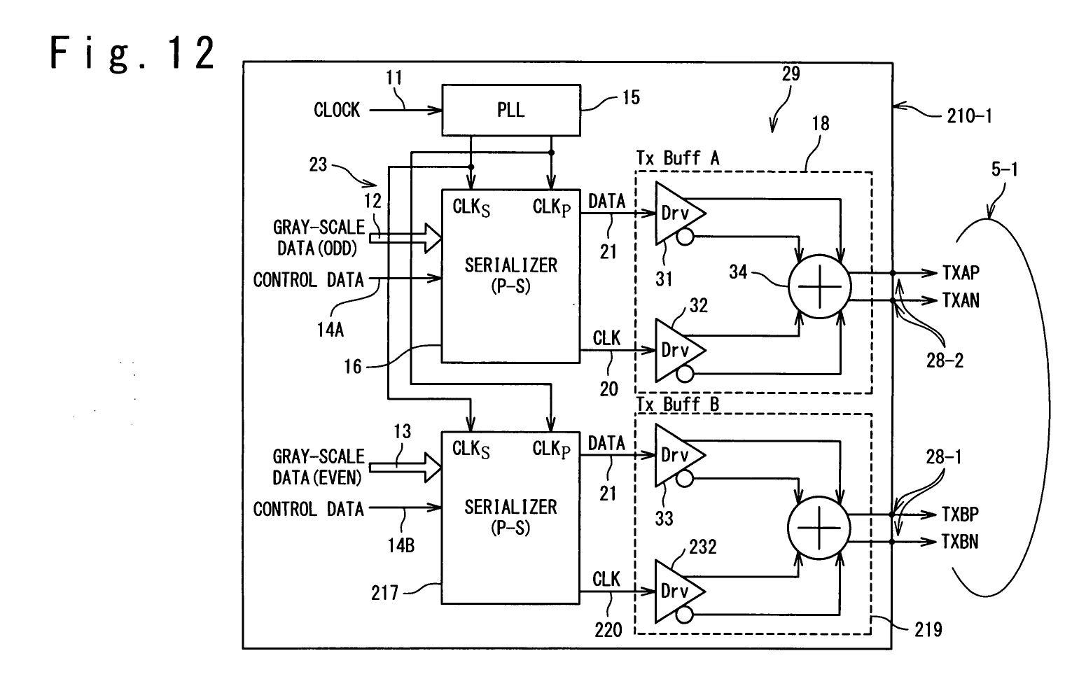

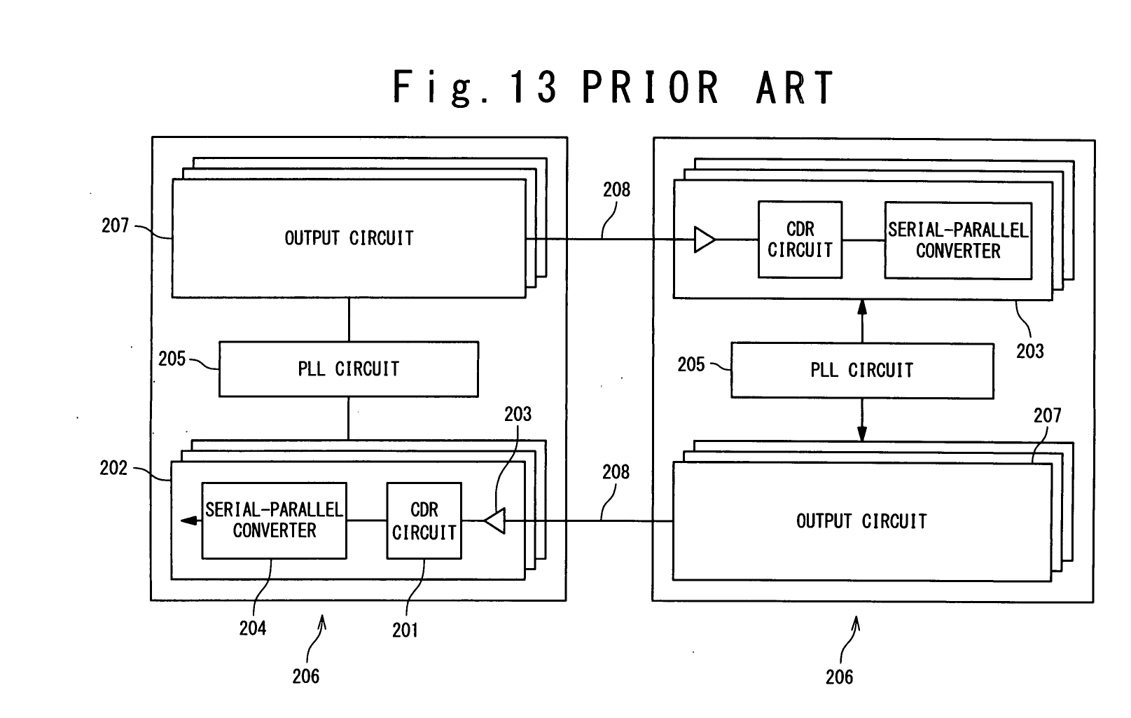

For example, FIG. 12 shows an exemplary configuration of a transmitter circuit 210-1 in an alternative embodiment. The same numerals denote the same components in FIGS. 2 and 12, and the descriptions thereof are not given. In the transmitter circuit 210-1, differently from the transmitter circuit 10-1 shown in FIG. 2, a hold circuit 217 connected to the transmission signal lines TXBP and TXBN incorporates a parallel-serial converter circuit having the same configuration as the hold circuit 16 and generates a clock signal 220. Similarly to the output buffer 18, the output buffer 219 connected to the hold circuit 217 amplifies the clock signal 220 and the serial output signal 22 with the amplifier circuits 33 and 232, and superposes the amplified clock signal 220 on the amplified serial output signal 22 to develop clock-embedded transmission signals on the signal lines TXBP and TXBN.

On the receiving side, the receiver circuit 80-1 shown in FIG. 2 is used to receive the clock-embedded transmission signals. In this case, the receiver circuit 80-1 recovers the clock signal superposed on the reception signals transmitted over the signal lines RXAP and RXAN and receives the data transmitted over the signal lines RXBP and RXBN in synchronization with the recovered clock signal; the clock signal superposed on the reception signals transmitted over the signal lines RXBP and RXBN is not subjected to clock recovery. In this case, the signal outputted from the data output D1 of the hold circuit 89 in the receiver circuit 80-1 is a clock signal, not carrying effective data bits to be used for subsequent signal processing. Although effective data are not outputted from the data output D1 of the hold circuit 89 in the receiver circuit 80-1, this also applies to the hold circuit 88, not affecting the operation of the receiver circuit 80-1.

The transmitter circuit configuration shown in FIG. 12 allows the use of the receiver circuit with the same configuration, regardless of whether clock signals are embedded into the transmission signals transmitted over all the transmission lines or a clock signal is embedded into the transmission signals transmitted over specific one of the transmission lines. This effectively improves the flexibility of the system implementation, while achieving miniaturization and power consumption reduction.

What is claimed is:

1. A receiver circuit comprising:
a plurality of input terminals;
a plurality of hold circuits holding reception signals received by said plurality of input terminals;
a detector circuit detecting clock bits from selected one of said reception signals to recover a clock signal in response to said detected clock bits; and
a clock circuit connected to said detector circuit and generating at least one internal clock signal from said clock signal;
wherein said plurality of hold circuits commonly receive said at least one internal clock signal and perform sampling of said reception signals commonly in synchronization with said at least one internal clock signal.

2. The receiver circuit according to claim 1, wherein each of said plurality of hold circuits includes a serial-parallel converter circuit which receives data bits of corresponding one of said reception signals in serial and outputs said received data bits in parallel.

3. The receiver circuit according to claim 2, wherein said detector circuit detects amplitude-modified portions of said one of said reception signals, said amplitude-modified portions having a different amplitude from other portions, and
wherein said detector circuit recovers said clock signal in response to said detected amplitude-modified portions.

4. The receiver circuit according to claim 3, wherein said amplitude-modified portions of said one of said reception signals have an amplitude larger than that of said other portions.

5. The receiver circuit according to claim 3, wherein said amplitude-modified portions of said one of said reception signals have an amplitude smaller than that of said other portions.

6. The receiver circuit according to claim 3, wherein said at least one internal clock signal generated by said clock circuit includes a plurality of pulse signals having a same cycle and different phases from each other, and
wherein each of said serial-parallel converter circuits are responsive to said plurality of pulse signals for receiving said data bits of said corresponding one of said reception signals in serial and outputs said received data bits in parallel.

7. The receiver circuit according to claim 6, wherein each of said serial-parallel converter circuits receives said data bits in serial in response to some but not all of said plurality of pulse signals.

8. The receiver circuit according to claim 6, wherein one(s) of said hold circuits associated with one(s) of said reception signals other than said one of said reception signals extracts internal control data from said reception signals in response to one of said plurality of pulse signals other than said some but not all of said plurality of pulse signals.

9. A transmitter circuit comprising:
a plurality of output terminals;
a clock generator circuit;
a plurality of hold circuits commonly connected to said clock generator circuit, wherein said plurality of hold circuits receive a plurality of signals, respectively, and output said plurality of signals in response to at least one clock signal received from said clock generator circuit; and
an output circuit connected to said plurality of hold circuits and outputting transmission signals to said plurality of output terminals, respectively,
wherein said output circuit generates one of said transmission signals through selectively incorporating clock bits into one of said plurality of signals outputted from said plurality of hold circuits.

10. The transmitter circuit according to claim 9, wherein each of said plurality of hold circuits includes a parallel-serial converter circuit which receives data bits of corresponding one of said transmission signals in serial and outputs said received data bits in parallel.

11. The transmitter circuit according to claim 10, wherein said output circuit generates said one of said transmission signals so that said amplitude of said one of said transmission signals at positions corresponding to said clock bits is different from that at other positions.

12. The transmitter circuit according to claim 11, wherein said amplitude of said one of said transmission signals at positions corresponding to said clock bits is larger than at said other positions.

13. The transmitter circuit according to claim 11, wherein said amplitude of said one of said transmission signals at positions corresponding to said clock bits is smaller that at said other positions.

14. The transmitter circuit according to claim 11, wherein said at least one clock signal generated by said clock generator circuit includes a plurality of pulse signals having a same cycle and different phases from each other,
wherein said clock generator circuit is responsive to a reference clock signal for generating said plurality of said pulse signals, and
wherein said parallel-serial circuits are responsive to said plurality of pulse signals for outputting said data bits of said transmission signals in parallel.

15. The transmitter circuit according to claim 14, wherein each of said parallel-serial converter circuits outputs said data bits in serial in response to some but not all of said plurality of pulse signals, and
wherein said output circuit incorporates said block bits into said one of said transmission signals in response to another of said plurality of pulse signals.

16. The transmitter circuit according to claim 15, wherein one(s) of said parallel-serial converter circuits associated with an other(s) of said transmission signals feeds control data into said other(s) of said transmission signals to said output circuits in response to said another of said plurality of pulse signals, and
wherein said output circuit incorporates said control data into said other(s) of said transmission signals.

17. The transmitter circuit according to claim 15, wherein said data bits include grayscale data indicative of grayscale levels of pixels of an image display panel.

18. A data transmission system comprising:
a clock generator circuit;
a plurality of output circuits commonly connected to said clock generator circuit and outputting a plurality of transmission signals, respectively, with said plurality of transmission signals synchronized with each other;
a control circuit connected to one of said plurality of output circuits and incorporating clock bits into one of said plurality of transmission signals, said one transmission signal being outputted from said one of said plurality of output circuits;
a plurality of transmission lines transmitting said plurality of transmission signals, respectively;
a plurality of input circuits connected with said plurality of transmission lines, respectively, and receiving said transmission signals, respectively; and
a clock circuit connected to one of said plurality of input circuits and detecting said clock bits from said one of said transmission signals to generate an internal clock signal in response to said detected clock bit,
wherein said plurality of input circuits sample said plurality of transmission signals transmitted over said plurality of transmission lines, respectively, commonly in synchronization with said internal clock signal.

19. The data transmission system according to claim 18, further comprising:
another control circuit connected to another of said plurality of output circuits and incorporating said clock bits into another of said plurality of transmission signals, said one transmission signal being outputted from said another of said plurality of output circuits.

20. The data transmission system according to claim 18, wherein one clock bit is incorporated into said one of said transmission signals for a predetermined number of data bits to be transmitted.
